(19) United States
(12) Patent Application Publication
(10) Pub. No.: US 2011/0309772 A1
(43) Pub. Date: Dec. 22, 2011

(54) SYSTEMS AND METHODS FOR LUMINESCENT DISPLAY

(75) Inventor: CHRISTIAN FORGEY, Round Rock, TX (US)

(73) Assignee: Light Bohrd, LLC

(21) Appl. No.: 13/163,238

(22) Filed: Jun. 17, 2011

Related U.S. Application Data
(60) Provisional application No. 61/355,799, filed on Jun. 17, 2010.

(51) Int. Cl. H05B 37/02; H05K 13/00

(52) U.S. Cl. 315/308; 315/307; 29/592.1

(57) ABSTRACT

A ruggedized luminescent display system for displaying electronic images or light from a surface of an object, according to various aspects of the present invention, may comprise a resilient transmissive material disposed within a cavity of the object and may have a surface that is configured to be substantially flush with an outer surface of the object. A light source may be disposed within the object and may emit light through the resilient transmissive material such that the light may be visible from the outer surface of the object. The light source may be electrically coupled to an integrated circuit board with a control system comprising a microcontroller that may control the emission of light from the light source in response to a signal. The microcontroller may receive the signal from a motion sensor that may be electrically coupled to the integrated circuit board and configured to detect the motion of the object.

### CROSS REFERENCE TO RELATED APPLICATION

This application claims the benefit of the U.S. Provisional Patent Application No. 61/355,799, filed Jun. 17, 2010, and incorporates the disclosure of the application by reference.

### BACKGROUND OF INVENTION

Skateboards and snowboards are equipment that may be used in a variety of recreational, sporting, and artistic activities. Users of these devices may share several commonalities. For example, users may apply a portion of their body to a board while utilizing the equipment. The board used in skateboarding may be referred to as a deck. The board used in snowboarding may be called a core or a base. The component materials used during board construction may be chosen to accommodate a specific type of user. Variables such as the user's age, size, skill level, and style may all be determinant factors considered when manufacturing boards.

The market and the cultures of skateboarding and snowboarding are very similar. Both endeavors have a global market, a wide user demographic, and have matured out of early demographic confines. Many different genres of boards may be available to accommodate typical users. For example, some common variants may include long boards, acrobatic boards, freestyle boards, and beginner's boards. Additionally, boards may comprise attention grabbing features such as shape, size, material, color, and accessories.

### SUMMARY OF THE INVENTION

A ruggedized luminescent display system for displaying electronic images or light from a surface of an object, according to various aspects of the present invention, may comprise a resilient transmissive material disposed within a cavity of the object and may have a surface that is configured to be substantially flush with an outer surface of the object. A light source may be disposed within the object and may emit light through the resilient transmissive material such that the light may be visible from the outer surface of the object. The light source may be electrically coupled to an integrated circuit board with a control system comprising a microcontroller that may control the emission of light from the light source in response to a signal. The microcontroller may receive the signal from a motion sensor that may be electrically coupled to the integrated circuit board and configured to detect the motion of the object.

### BRIEF DESCRIPTION OF THE DRAWINGS

A more complete understanding of the present invention may be derived by referring to the detailed description when considered in connection with the following illustrative figures. In the following figures, like reference numbers refer to similar elements and steps throughout the figures.

FIGS. 1A-1B representatively illustrate a cross-sectional view of an exemplary embodiment of a luminescent display system coupled to an object wherein a light source is located proximate to a transmissive material;

FIGS. 2A-2B representatively illustrate a cross-sectional view of an exemplary embodiment of a luminescent display system coupled to an object wherein a light source is embedded in a transmissive material;

FIG. 3 representatively illustrates a schematic of an exemplary embodiment of an integrated circuit board;

FIGS. 4A-4B representatively illustrate an exemplary embodiment of a boardsport medium coupled to a luminescent display system;

FIG. 5 is a flow chart that representatively illustrates an exemplary method of manufacture of a luminescent display system where a light source is separate from a transmissive material; and

FIG. 6 is a flow chart that representatively illustrates an exemplary method of manufacture of a luminescent display system where a light source is embedded within a transmissive material.

Elements and steps in the figures are illustrated for simplicity and clarity and have not necessarily been rendered according to any particular sequence or scale. For example, steps that may be performed concurrently or in different order are illustrated in the figures to help to improve understanding of embodiments of the present invention.

### DETAILED DESCRIPTION OF EXEMPLARY EMBODIMENTS

The present invention may be described in terms of functional block components and various processing steps. Such functional blocks may be realized by any number of components configured to perform the specified functions and achieve the various results. For example, the present invention may employ various process steps, apparatus, systems, methods, etc. In addition, the present invention may be practiced in conjunction with any number of systems and methods for providing luminescence at a surface of an object, and the system described is merely one exemplary application for the invention. Further, the present invention may employ any number of conventional techniques for implementing luminescence at the surface of the object.

The particular implementations shown and described are illustrative of the invention and its best mode and are not intended to otherwise limit the scope of the present invention in any way. Indeed, for the sake of brevity, conventional manufacturing, connection, preparation, and other functional aspects of the system may not be described in detail. Furthermore, the connecting lines shown in the various figures are intended to represent exemplary functional relationships and/or steps between the various elements. Many alternative or additional functional relationships or physical connections may be present in a practical system.

Various representative implementations of the present invention may be applied to any system or method for providing a luminescent display system configured to display electronic images or light from the surface of an object. The object may comprise any suitable medium for containing and supporting the luminescent display system. For example, the object may be a boardsport medium, such as a skateboard, snowboard, surfboard, or bodyboard. The object may also comprise body protective clothing or a helmet.

In an exemplary embodiment, according to various aspects of the present invention, the luminescent display system may be coupled to the object in a configuration that seals the components of the luminescent display system within the object and allows light emitted from the luminescent display system to be visible from an outer surface of the object. The components of the luminescent display system may be placed in any suitable location in the object to optimize their conditions for use. For example, any component may be placed at the top, bottom, center, front, back, or near a structurally reinforced portion of the object, such as near the trucks of a skateboard. In one embodiment, one or more components of the luminescent display system may occupy a sealed cavity within the object wherein light may be visible through an acrylic sealed window. The cavity may be created during manufacturing of the object. In another embodiment, the components of the luminescent display system may be incorporated into the object by any suitable method, such as being pressed between layers of component material of the object.

In one embodiment, the luminescent display system may comprise a fixed luminescent display that the user can turn off and/or on. In another embodiment, the luminescent display system may comprise a programmable display that the user may control. In yet another embodiment, the luminescent display system may display electronic images or light in response to a signal, such as from a motion sensor detecting the motion of the object. The luminescent display may display electronic images or light from one, multiple, or all surfaces of the object.

The components of the luminescent display system may be coupled to the object in any suitable arrangement. For example, the components may be provided separately for mounting each component to a different location within the object such as for strategically placing each component in a location that may protect that component from shock, breakage, or excessive wear. In one embodiment, the components of the luminescent display system may be integrated into a pre-assembled module that may be attached to one or several layers, sandwiched between several layers of component material of the object or in a cavity of the object.

The luminescent display system may be configured to be ruggedized to resist wear and damage from the physical stress of the environment and harsh conditions during use. For example, the luminescent display system may be used in environmental conditions that may be extreme in temperature, humidity, precipitation such as snow, sleet, or rain, and corrosive salinity such as salt water. Further, the user may subject the luminescent display system to physically stressful impact forces such as direct blunt forces, forces from the impact of a sharp object, bending, twisting, and the like.

In one embodiment, the luminescent display system may be placed within one or more cavities of the object or between layers of the object such that the components are protected from exposure to the environment. In another embodiment, the components of the luminescent display system may themselves comprise materials that resist wear. For example, the components may thin or flexible to enhance durability.

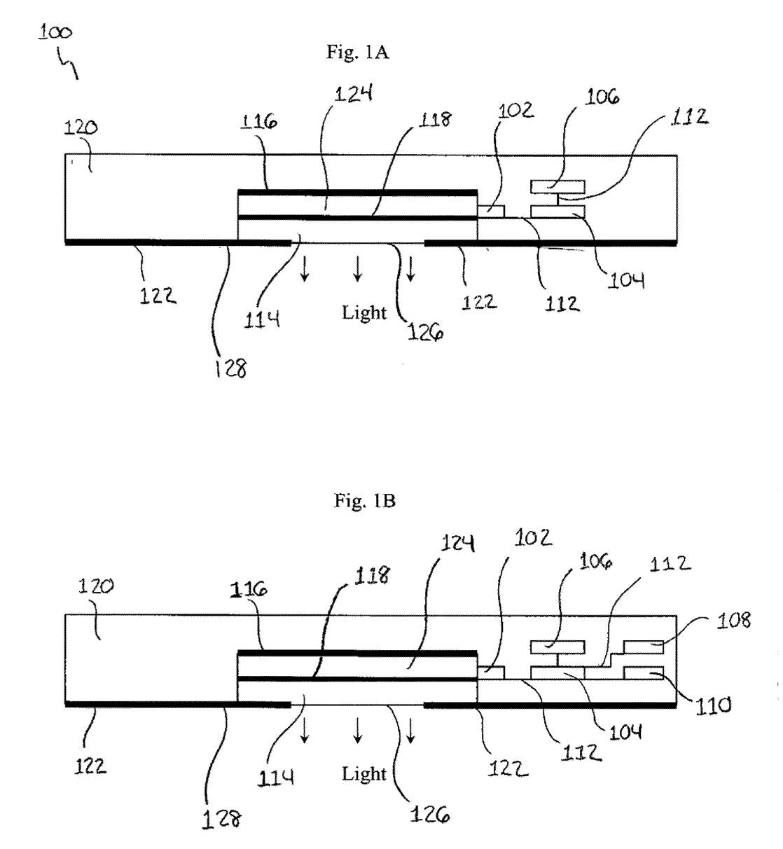

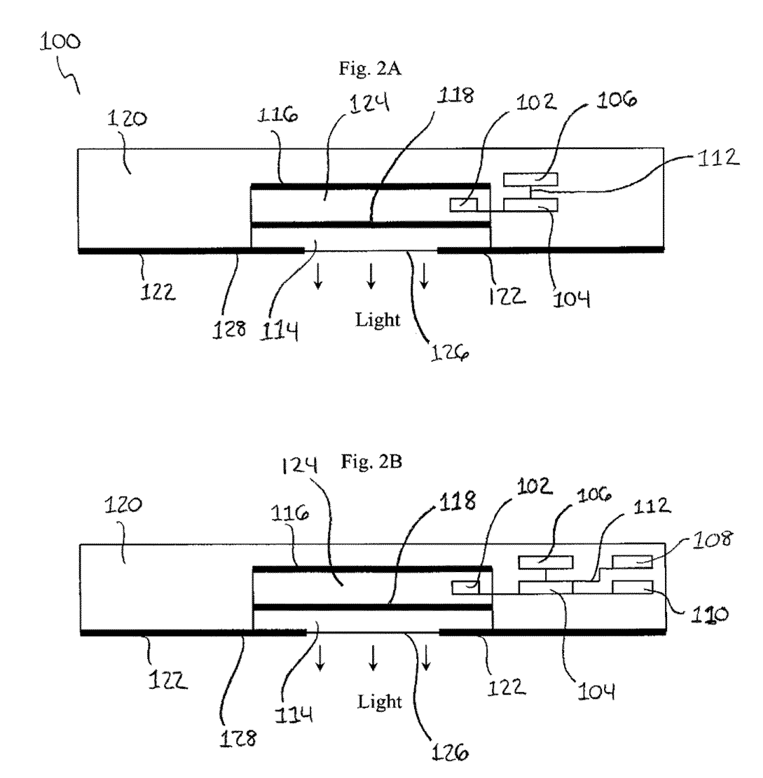

Referring now to FIGS. 1A-1B and 2A-2B, systems and methods for providing the luminescent display system according to various aspects of the present invention may be representatively illustrated by a luminescent display system 100. In some embodiments, the luminescent display system 100 may comprise a light source 102, an integrated circuit board 104, a power source 106, and one or more power conduits 112.

The integrated circuit board 104 may comprise any printed circuit board that may be a substrate, which may mechanically and electrically support electronic components. In one embodiment, the electronic components may be printed directly onto the integrated circuit board 104. In another embodiment, the integrated circuit board 104 may comprise connection points for electronic components. In yet another embodiment, the integrated circuit board 104 may comprise both directly attached electronic components and connection points for electronic components.

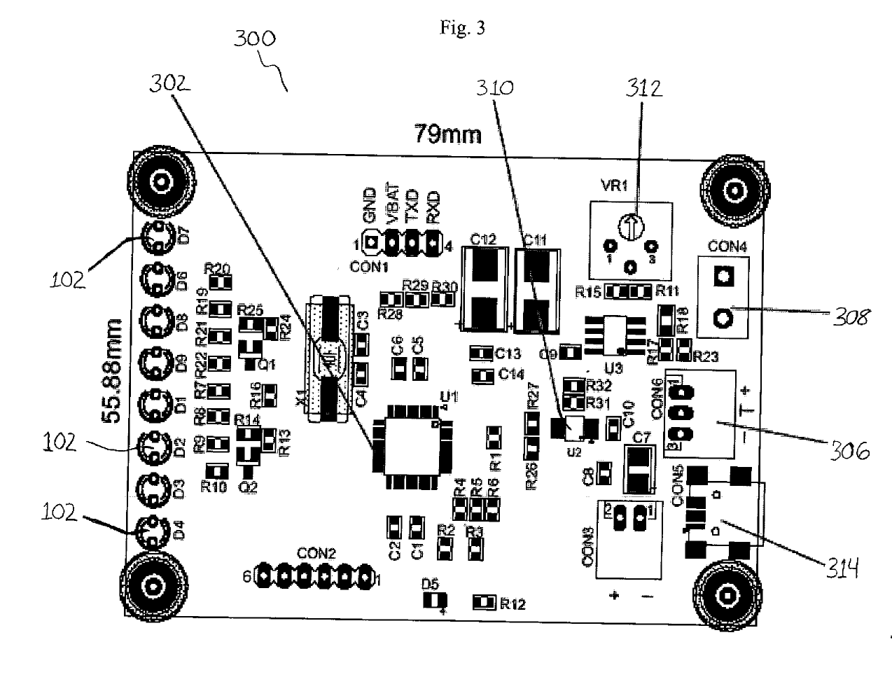

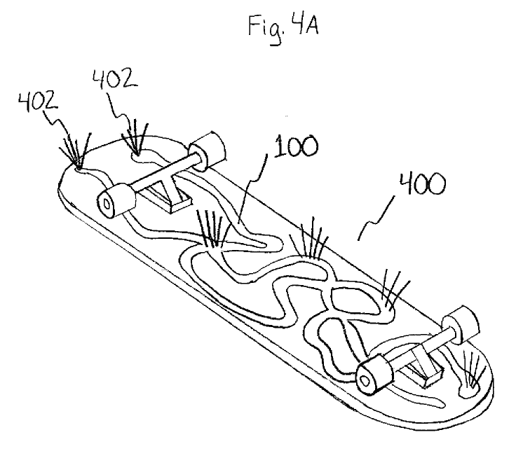

Referring to FIG. 3, in an exemplary embodiment of the present invention, the integrated circuit board 104 may be an integrated circuit board 300. One or more electronic components may be electrically coupled directly onto the integrated circuit board 300, by conventional processes such as soldering or using wire connectors. In another embodiment, one or more electronic components may be located apart from the integrated circuit board 300 and may be electrically coupled to the integrated circuit board 300 by the power conduit 112.

In an exemplary embodiment, according to various aspects of the present invention, the integrated circuit board 300 may comprise a microcontroller 302, a battery charger 310, a motion sensor 312, a USB charger 314, and a battery connector 306. The microcontroller 302, battery charger 310, motion sensor 312, USB charger 314, and the battery connector 306 may be directly electrically coupled to the integrated circuit board 300. In one embodiment, the integrated circuit board 300 may comprise one or more directly electrically coupled light sources 102, a piezoelectric transducer 308, and a magnetic induction circuit (not shown). In another embodiment, the light source 102, the piezoelectric transducer 308, and the magnetic induction circuit may be located remotely from the integrated circuit board 300 and be electrically coupled to the integrated circuit board 300 by the power conduit 112 (not shown). Further, in another embodiment, the integrated circuit board 300 may comprise a power source connector 306 for electrically coupling a remotely located power source 106 to the integrated circuit board 300 via the power conduit 112.

The integrated circuit board 300, may be incorporated into any suitable location in the object 120. As shown in FIGS. 1A-1B and 2A-2B, the integrated circuit board 104 may be embedded within the object 120. For example, the object 120 may be a skateboard deck or a snowboard base, wherein the integrated circuit board 104 may be disposed between two layers of component material during the manufacturing process for creating the skateboard deck or snowboard base, as detailed below. In one embodiment, the integrated circuit board 104 may be located in the head or tail section of the skateboard deck or snowboard base, wherein the power conduit 112 extends from the integrated circuit board 104 to the light source 102 and/or the power source 106 that may be placed in other locations throughout the object 120.

In one embodiment, the integrated circuit board 104 may comprise a control system comprising a microcontroller 302 for controlling various functions of components of the luminescent display system 100. The microcontroller 302 may comprise any suitable electronic components such as memory, drivers, a clock, a microprocessor, and the like. For example, the microcontroller 302 may control component functions according to local signals from a nearby sensor, such as the motion sensor 312, and/or the microcontroller 302 may be adapted to control component functions according to communications from remote systems. The microcontroller 302 may also comprise a programmable microcontroller or CPU that may process and transmit instructions to the luminescent display system 100 after a user uploads data from an interface such as a computer. The microcontroller 302 may be configured to transmit, receive, and/or exchange data through any system for exchanging data, such as, for example, the Internet, an intranet, an extranet, Wide Area Network (“WAN”), Local Area Network (“LAN”), WIFI, WIMAX, satellite communications, intermediate storage systems, radio frequency communications, a mesh network protocol such as Zigbee, wireless 802.11g and/or the like. In one embodiment, the user may upload a program or instruction for controlling the light source 102 wirelessly to the microcontroller 302, such as through a wireless Internet connection.

The microcontroller 302 may process the signal to control the light source 102. The microcontroller 302 may activate the light source 102 to emit a desired color and/or pattern of light, such as playing a video, blinking, displaying pictures and/or text, and the like.

The microcontroller 302 may also communicate with other components, such as the power source 106. The microcontroller 302 may receive a signal from the power source 106 that the amount of charge is sufficient for operating the luminescent display system 100, which may prevent the microcontroller 302 from activating the power source charger 310. The microcontroller 302 may also receive a signal from the power source 106 that the amount of charge is insufficient for operating the luminescent display system 100, which may result in the microcontroller 302 activating the power source charger 310 to charge the power source 106.

The microcontroller 302 may comprise at least one of a switch, memory device, microcontroller, chip, antennae, and/or communication port such as a USB. The memory device may be embedded or non-embedded technology that may be volatile or non-volatile, such as random access memory or a read only memory that may deliver instructions for the control of the luminescent display system 100. Certain embodiments of the microcontroller 302 may include removable memory devices such as cards, sticks, discs, or other storage devices. The microcontroller 302 may comprise any memory storage device known to one skilled in the art either now existing and/or hereinafter produced, developed, and/or implemented in the future.

In one embodiment, the microcontroller 302 may comprise a switch. The switch may comprise a button, a touch sensitive pad, antennae, port, or any other device that may facilitate communication of information between a user and the luminescent display system 100. In one embodiment, the microcontroller 302 may comprise multiple representative elements that work alone or together to activate, deactivate, or impose instructions upon the luminescent display system 100. Representative embodiments may comprise an on/off switch connected to a central processing unit (CPU) that may control any component of the luminescent display system 100. In another embodiment, the microcontroller 302 may comprise a simple on/off touch pad and/or a radio-frequency identification (RFID) antennae that may activate and deactivate the luminescent display system 100 when the object 120 is grasped by a user or exposed to a user's RFID signal.

The microcontroller 302 may be electrically coupled to the power source 106 through the integrated circuit board 300 by the power conduit 112 such that the power source 106 provides electricity to drive the microcontroller 302. In one embodiment, the microcontroller 302 may be directly electrically coupled onto the integrated circuit board 104.

In one embodiment, the microcontroller 302 may activate or deactivate the light source 102 in response to the motion of the object 120. For example, the motion sensor 108, a micro electric mechanical chip, or other suitable device may sense the environment around the object 120 and provide a signal to the microcontroller 302. Certain representative embodiments of the microcontroller 302 may gather optical, kinetic, thermal, or other information surrounding the object 120 and may provide the signal to the microcontroller 302 based on the information. The microcontroller 302 may activate or deactivate the light source 102 in response to the signal.

In one embodiment, the motion sensor 108, may comprise a device such as an accelerometer that may quantify the proper acceleration of the object 120 such as by measuring the specific force or g-force of the object 120. For example, the object 120 may be a skateboard in which a user rides over a surface such as the ground, rough terrain, and/or over jumps for performing tricks. The accelerometer may measure the acceleration of the skateboard over the surface as the skateboard reaches higher speeds and, in turn, provide a signal to the microcontroller 302 to activate or deactivate the light source 102 based on that signal. In another exemplary embodiment, the motion sensor 108 may comprise a piezoelectric transducer that may convert the application of pressure, acceleration, or force to an electrical charge that is detected by the microcontroller 302.

In one embodiment, referring to FIGS. 1A and 2A, the motion sensor 108 may be electrically coupled directly onto the integrated circuit board 104, such as the motion sensor 312 shown in FIG. 3. In another embodiment, referring to FIGS. 1B and 2B, the motion sensor 108 may be independent of and electrically coupled to the integrated circuit board 104. The motion sensor 108 that is apart from the integrated circuit board 104 may therefore be located in another portion of the object 120.

The light source 102 may comprise any suitable structure and/or device that may emit light, such as at least one light emitting diode (LED), organic light emitting diode, light emitting electrochemical cell, quantum dot, thick-film dielectric technology, or micro-display. In one embodiment, the light source 102 may be electrically coupled to the microcontroller 302 through the power conduit 112 such that the power source 106 may provide electricity to drive the light source 102. In another embodiment, the light source 102 may be directly electrically coupled to the microcontroller 302 such as by an electrical wire connector and/or a soldered connection.

In an exemplary embodiment, the light source 102 may comprise any suitable LED, such as a red-green-blue LED and/or a phosphor converted LED. The light source 102 may be configured to emit any wavelength of light. In one embodiment, the LED may comprise gallium-based crystals such as gallium nitride, indium gallium nitride, gallium aluminum phosphide, and the like.

In another representative embodiment of the luminescent display system 100, the light source 102 may comprise a thick film dielectric luminescent technology (TDEL). In one embodiment, the TDEL may comprise a phosphor display that combines thick film and thin film technology. In another embodiment, the TDEL may be a light source 102 that is sandwiched between materials and/or films that may be transmissive or opaque. The TDEL may comprise any materials that are highly resistant to temperature extremes and breakage that may result from kinetic impact.

In some embodiments, the light source 102 may comprise an organic light emitting diode (OLED). The light source 102 may comprise any suitable OLED, such as an active or a passive matrix OLED. In one embodiment, an active matrix OLED may provide a low power, rollable display that may attach to any object 120. In some embodiments, the light source 102 may also comprise a passive matrix OLED alternative that is configured for displays requiring less malleability. In another embodiment the OLED may be a phosphorescent OLED that may be an energy efficient light source.

In some embodiments, the light source 102 may comprise a light emitting electrochemical cell (LEC) that may achieve luminescence with an organic phosphorescent display. Further, the LECs may have slower turn on times that may be suitable for providing static luminescence when applied at the surface of the object 120. In one embodiment, the LEC may comprise at least one of graphene, gold, a blended carbon nanotube, and a polymer light emitting diode. In some embodiments, the light source 102 may comprise the LEC that may be implemented on a printed film that may be attached to the object 120.

In one embodiment, the light source 102 may comprise one or more quantum dots. A possible variant using quantum dot technology may comprise a light source 102 that responds to external stimulus such as voltage or light. In another embodiment, quantum dot technology may be combined in a low power film that may be a rechargeable power source such as a photovoltaic cell. Some embodiments of a quantum dot light source 102 may emit white light, or the quantum dots may produce red, green, or blue light, or any another electromagnetic wavelength.

Representative embodiments of the light source 102 may comprise any LED, TDEL, OLED, LEC, and/or quantum dot technology known to one skilled in the art either now existing and/or hereinafter produced, developed, and/or implemented in the future.

Referring to FIGS. 1A and 1B, the light source 102 may be located proximate to the transmissive material 114 and configured to emit light through the transmissive material 114. For example, in an exemplary embodiment, one or more light sources 102 may be located directly adjacent to the transmissive material 114, wherein the power conduit 112 extends from the light source 102 to the power source 106 and/or the integrated circuit board 104 which may be in other locations throughout the object 120. The light source 102 may be embedded within the object 120. For example, the object 120 may be a skateboard deck or a snowboard base, wherein the light source 102 may be disposed between two layers of component material during the manufacturing process for creating the skateboard deck or snowboard base, as detailed below.

Referring to FIGS. 2A and 2B, the light source 102 may be embedded in the transmissive material 114. For example, the light source 102 may be electrically coupled to the power conduit 112, which may extend from the light source 102 to the power source 106 and/or the integrated circuit board 104. In an exemplary embodiment of the present invention, the light source 102 that may be electrically coupled to the power conduit 112 may be embedded in the transmissive material 114 during a manufacturing process of the transmissive material 114, such as curing and/or molding processes.

The luminescent display system 100 may comprise a power source 106. The power source 106 may comprise any suitable structure and/or device that may provide power. For example, in various embodiments of the present invention, the power source 106 may comprise a battery such as an energy harvesting battery, a rechargeable battery, a nanowire cell, a solar cell, thin film cell, a lithium polymer battery, a super capacitor, button or coin cells, an alkaline battery, multiple electrode cells, energy harvesting transducers, and/or solid state rechargeable thin-film micro-energy storage devices.

The power source 106 may also comprise and/or be coupled to a solar cell. In some embodiments, the solar cell may provide power directly or indirectly to the luminescent display system 100, and/or it may be attached to an electrical storage medium, such as a battery. In various embodiments, the solar cell may comprise thin film technology, organic, polymer, and/or silicon-based cells.

In some embodiments, the power source 106 may comprise a device that produces electrical energy via changes in acceleration or motion, such as an energy harvesting transducer. In one embodiment, the power source 106 may derive power from a power production mechanism attached to accessories associated with the object, such as a skateboard. For example, the power source 106 may derive power from a power generator that may use the rotational energy associated with wheels attached to the skateboard. The power source 106 may comprise any battery, electrical storage device, and/or electrical production device known to one skilled in the art either now existing and/or hereinafter produced, developed, and/or implemented in the future.

As shown in FIGS. 1A-1B and 2A-2B, the power source 106 may be electrically coupled to the power conduit 112, which may conduct electricity from the power source 106 to drive the light source 102 and/or the components of the integrated circuit board 300. In one embodiment, the battery may be removable or connected to any component of the luminescent display system 100 in a semi-permanent or permanent configuration.

The power source 106 may comprise a battery that is substantially resistant to wear from physical and environmental stress, such as the force from an impact or exposure to extreme temperatures. In an exemplary embodiment, the battery may comprise a substantially flexible lithium polymer pouch cell battery that may be incorporated into the object 120 at a location that is protected from wear. For example, where the object 120 is a skateboard, the battery may be located in the tail section of the skateboard and/or near the wheel base or trucks.

In one embodiment, the power source 106 may be configured to be rechargeable by any suitable method such as a conventional direct electrical connection to a recharge circuit or indirect recharging methods. For example, in one embodiment, the power source 106 may be indirectly recharged by electromagnetic induction in which a magnetic field is used to wirelessly induce a current into a receiving coil with a magnetic induction circuit 110 that is connected to the power source 106. In one embodiment, as shown in FIGS. 1B and 2B, the magnetic induction circuit 110 may be separate from and electrically coupled to the integrated circuit board 104. In another embodiment, the magnetic induction circuit 110 may be electrically coupled directly on the integrated circuit board 104 (not shown).

In an exemplary embodiment, the magnetic induction circuit 110 may be a Powermat receiver incorporated into the object 120 and electrically coupled to the integrated circuit board 104 through the power conduit 112. The magnetic field may be provided by the Powermat mat. In another embodiment, the power source 106 may be indirectly recharged by harvesting energy from the environment such as with a piezoelectric transducer that may be electrically coupled to the integrated circuit board 104.

Referring to FIGS. 1A-1B and 2A-2B, the power source 106 may be electrically coupled to the integrated circuit board 104 by a power conduit 112. The power source 106 may be embedded within the object 120 in any suitable location. For example, the power source 106 may be located on the top of the object 120, such as where the power source 106 requires solar energy for recharging. In one embodiment, the object 120 may be a skateboard deck or a snowboard base, wherein the power source 106 may be disposed between two layers of component material during the manufacturing process for creating the skateboard deck or snowboard base, as detailed below. In an exemplary embodiment of the present invention, the power source 106 may be located in the tail section of the skateboard deck proximate to the integrated circuit board 104.

The power conduit 112 may be electrically coupled to the power source 106 to provide power to the light source 102 and the integrated circuit board 104. The power conduit 112 may comprise any material that may convey power such as electricity. For example, the power conduit 112 may comprise a solid or stranded wire, a conductor, a thick film dielectric technology, a flexible electronic substrate, and/or a printed circuit board, a thick film, printed, organic, inorganic electronic technology, and/or stretchable or flexible substrates for attachment and conduction. In some embodiments, the power conduit 112 may comprise any suitable medium for fixing conducting materials and/or attaching components of the luminescent display system 100.

In one embodiment, the power conduit 112 may comprise at least one wire. In some embodiments, the wire may comprise any conducting material such as solid wire and/or stranded wire. In a representative embodiment, the power conduit 112 may comprise a multiwire board, with solid or stranded wire embedded in a plastic resin. In some embodiments, the power conduit 112 may be permanently attached to any component of the luminescent display system 100 or it may be removable and/or interchangeable. The power conduit 112 may also be configured to allow the attachment of any component of the luminescent display system 100.

The transmissive material 114 may comprise any suitable material that may fully or partially transmit visible light. For example, the transmissive material 114 may transmit light emitted from the light source 102. In one embodiment, the transmissive material 114 may be proximate to the power conduit 112, the light source 102, the power source 106, and/or the integrated circuit board 104. In some embodiments, the transmissive material 114 may comprise acrylic, polycarbonate and/or thermoplastic polymers, a glass material, an elastomer such as a urethane polymer, biaxially-oriented polyethylene terephthalate material such as Mylar®, and/or a composite or non-composite material of synthetic or organic origin. The transmissive material 114 may comprise one or multiple layers of a single material or multiple layers of different materials to achieve any desired resilient properties and/or optical qualities.

Further, the transmissive material 114 may comprise any suitable thickness. For example, in an exemplary embodiment of the present invention, the thickness of the transmissive material may range from an edge thickness of approximately 1.27 mm to a thickness of 3 mm.

In one embodiment, the transmissive material 114 may be resistant to shock from an impact and erosion or wear from environmental contaminants such as salt water. In one embodiment, the optical quality of the transmissive material 114 may be resistant to alteration. For example, the transmissive material 114 may comprise a transparent material that may be resistant to scratching and abrasion that may otherwise render portions of the surface of the transmissive material 114 to be opaque, thus obscuring the transmission of light by the light source 102. The transmissive material 114 may be resistant to abrasion from rocks, board slides along rough surfaces such as a sidewalk curb, and hard ice and snow wherein the transmissive material 114 is configured to be on the bottom surface of a skateboard or a snowboard. The resistance of the transmissive material 114 may allow the light emitted from the light source 102 to be transmitted through the transmissive material 114 unimpeded, thereby preserving the optimal optical quality of the transmissive material 114.

Referring to FIGS. 1A-1B and 2A-2B, the transmissive material 114 may be disposed within a cavity 124 of the object 120. The cavity 124 may comprise an aperture created within one or more sides of the object 120 and may be configured to receive the transmissive material 114 which may fill the entire cavity 124. In one embodiment, a surface 126 of the transmissive material 114 may be configured to be positioned substantially flush with an outer surface 128 of the object 120 such that damage from surfaces that the object 120 encounters is further minimized. The outer surface 128 of the object 120 may be at least partially covered with a design element 122. For example, where the object 120 is a skateboard, aligning the transmissive material 114 flush with the outer surface of the skateboard such that the outer surface of the skate board is smooth will prevent shock to the sides of the transmissive material 114, such as from the impact from a boardslide that may otherwise catch an exposed edge of the transmissive material 114. In an exemplary embodiment, the transmissive material 114 may be secured into the cavity of the object 120 during manufacturing of the object 120.

In a representative embodiment of the present invention, the transmissive material 114 may comprise an acrylic material. In one embodiment, the acrylic material may be translucent, opaque, tinted, and/or colored. In another embodiment, the acrylic material may be smooth and/or may have surface texture, such as patterned indentations, that may provide a desired optical property such as enhancing the light output through the transmissive material 114. The acrylic material may provide visual effects when coupled to the light source 102. In an exemplary embodiment, the acrylic transmissive material 114 may comprise a Clarex® cast cell acrylic sheet from Astra Products, Inc.

In another embodiment, the transmissive material 114 may comprise polycarbonate or thermoplastic polymers. For example, the polymers may comprise polystyrene, celluloid, polycarbonate, polyethylene, and/or various mixtures of other polymer materials. The polymers may be scratch resistant, strong, durable, and/or stable over a wide range of temperatures.

The transmissive material 114 may comprise composite or non-composite materials such as synthetic or organic materials. The composite or non-composite visual properties of the transmissive material 114 may provide color changes or changes in the opacity or reflective nature of the transmissive material 114. In one embodiment, the composite or non-composite material of synthetic or organic origin may provide durability, reflectiveness, safety, strength, texture, ease of manufacture such as the ability to be machined or molded, and/or ease of disposal.

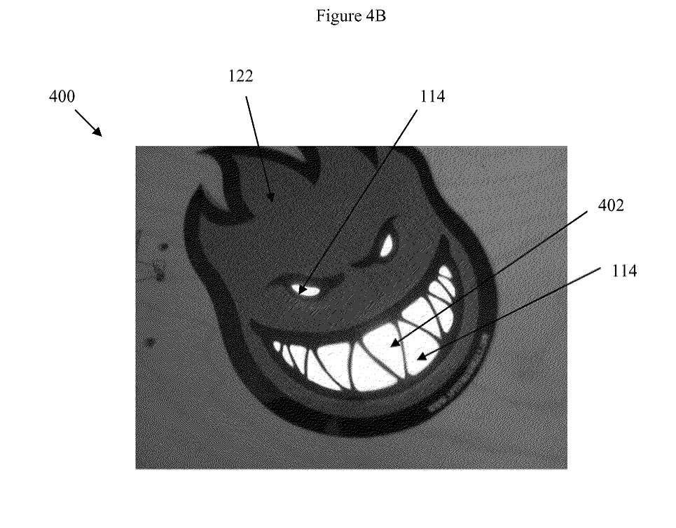

The transmissive material 114 may be located in any suitable position on the object 120 such that a viewer may see the display of electronic images and/or light from the luminescent display system 100. In one embodiment, referring to FIG. 4A where the object 120 is a skateboard, the transmissive material 114 may create a winding pattern along the underside of the skateboard creating a trail of light 402. In another embodiment, the design element 122 such as a sticker or paint may form a pattern over the transmissive material 114. For example, referring to FIG. 4B, a sticker design of a face with flaming hair may have a transparent mouth and eye portion overlaying the transmissive material 114. The light 402 emitted from the light source 102 may create glowing eyes and a glowing mouth in the design.

In an exemplary embodiment of the present invention, a reflective film 116 may be applied to one or more surfaces of the transmissive material 114 to at least one of enhance, intensify, diffuse, and/or concentrate light emitted from the light source 102 that is transmitted through the transmissive material 114. The reflective film 116 may direct light from the light source 102 in any suitable direction, such as laterally, upwards, or downwards. For example, the reflective film 116 may be applied to the surface of the transmissive material 114 that faces an internal portion of the object 120, such as in a cavity occupied by the transmissive material 114. The light from the light source 102 may reflect off the reflective film 116 to an opposite side of the transmissive material 114 that is substantially flush with an outer surface of the object 120. The reflection of light to the outer surface of the object 120 may intensify the light that is visible from the outer surface of the object 120.

The reflective film 116 may comprise any suitable reflective material. In one embodiment, the reflective film 116 may comprise retroreflective sheeting such as Diamond Grade DG³ Reflective Sheeting Series 4000 manufactured by 3M. The reflective film 116 may be applied to the transmissive material using any suitable methods, such as cutting the reflective film 116 to conform to the size and dimensions of the transmissive material 114 and/or using a pressure-sensitive adhesive or a lamination process to secure the reflective film 116 to the transmissive material 114.

In one embodiment, according to various aspects of the present invention, a prismatic film 118 may be applied to the transmissive material 114. The prismatic film 118 may be configured to maximize the brightness of the light emitted from the light source 102 through the transmissive material 114, such as by increasing the efficiency of backlighting. The prismatic film 118 may reduce the power consumption of the light source 102 and increase the time the power source 106 provides power to the light source 102 without charging, due to the need for less intense light.

The prismatic film 118 may comprise a sheet material that comprises micro-replicated prismatic cone-like structures that may control the exit angle of light from the transmissive material 114. The cone-like structures on the prismatic film 118 may refract light emitted by the light source 102 that reaches the cone-like structure and direct that light towards the outer surface of the object 120 (toward the viewer). The prismatic film 118 may also reflect light that does not reach the cone-like structures backwards to be recycled until the light reaches the cone-like structures and exits at the desired angle. For example, in one embodiment, the prismatic film 118 may comprise Vikuiti Thin Brightness Enhancement Film 90/24 (TBEF) from 3M. In another embodiment, the prismatic film 118 may comprise Vikuiti Transmissive Right Angle Film II (TRAF II) from 3M, which may be configured to redirect light emitted from the side of the transmissive material 114. In yet another embodiment, TBEF and TRAF II film may be used together as a prismatic film 118.

In one embodiment, the prismatic film 118 may be disposed between two layers of the transmissive material 114, as shown in FIGS. 1A-1B and 2A-2B. The light source 102 may emit light toward and through the transmissive material 114, encountering the prismatic film 118, which may enhance the brightness of the light as it exits to the surface of the object 120.

The luminescent display system 100 may be coupled to an object 120 comprising any suitable object, article, device, component material, and/or surface for attachment and/or coupling with the luminescent display system 100. For example, the object 120 may be a wall, building material, board, table, door, wood, plastic, helmet, composite surface, organic surface, synthetic surface, film, and/or resin. In one embodiment, the object 120 may be a boardsport medium such as a skateboard, snowboard, snow or water skis, sleds, kiteboards, bodyboards, wakeboards, or surfboards. In another embodiment, the object 120 may be clothing such as a fireman's protective turnout coat or motocross clothing such as an under roost protective deflector or chest and back protectors.

The luminescent display system 100 may be coupled to the object 120 in any suitable manner. For example, the luminescent display system 100 may be bonded, glued with an adhesive, welded, embedded, and/or attached mechanically with a fastener such as bolt and/or screws. In one embodiment, one or more components of the luminescent display system 100 may be coupled to or sandwiched between one or more layers of the component material of the object 120, such as during the manufacturing of the object 120. In another embodiment, one or more components of the luminescent display system 100, such as the transmissive material 114, may be coupled within a cavity, space, or indentation of the object 120 during the manufacturing of the object 120 such that it may be visible from more than one direction, view, or surface of the object 120. In another embodiment, the transmissive material 114, such as acrylic, may be attached into a recessed cavity of the object 120 that may be carved from the object 120.

In an exemplary embodiment of the present invention, referring to FIGS. 4A-4B, the luminescent display system 100 may emit light 402 while coupled to the object 120, such as a skateboard deck 400 or snowboard base (not shown). In various embodiments, the luminescent display system 100 may be implemented within or at the surface of the skateboard deck 400 or snowboard base. The skateboard deck 400 or snowboard base may comprise any suitable component material. For example, the component material may comprise a plurality of layers of wood veneer adhered together with an adhesive, such as a glue, wherein the adhered wood veneer layers may be molded into a shape for the skateboard deck 400, such as using a pressurized mold. In one embodiment, the component material may comprise a plurality of layers wood veneers, solid wood, plywood, particle board, metal, metal alloys, fiberglass, plastic, composite material of organic origin, composite of synthetic origin, and/or a composite consisting of materials of both organic and synthetic origin. In another embodiment, the snowboard base or core may comprise a plurality of layers of component material such as at least one of a wood center or core, fiberglass, composite material, acrylic, metal such as steel, and polymer material.

In an exemplary embodiment of the present invention, the luminescent display system 100 may comprise a design element, such as design element 122. The design element 122 may comprise any suitable material that may provide an artistic or stylized decoration to the luminescent display system 100. For example, the design element 122 may comprise a sticker, paint, and/or a material applied to the object 120, such as by screenprinting, a heat transfer process, and adhesive, a fastener, a hook and loop closure, and/or a combination thereof. In one embodiment, the design element 122 may be coupled to the transmissive material 114. In another embodiment, the design element 122 may be coupled to both the transmissive material 114 and the object 120.

In an exemplary embodiment, the design element 122 may cover a surface of the skateboard deck 400, such as a bottom surface and/or a top surface. The design element 122 may comprise cut-out portions, translucent colored portions, or a screenprinted mesh-type of material to allow the luminescence 402 to show through the design element 122. For example, the luminescence 402 may show through the design element 122 as a cut-out pattern in any shape to provide an artistic decoration, such as a skull, snake, face, animal, winding path, or flames.

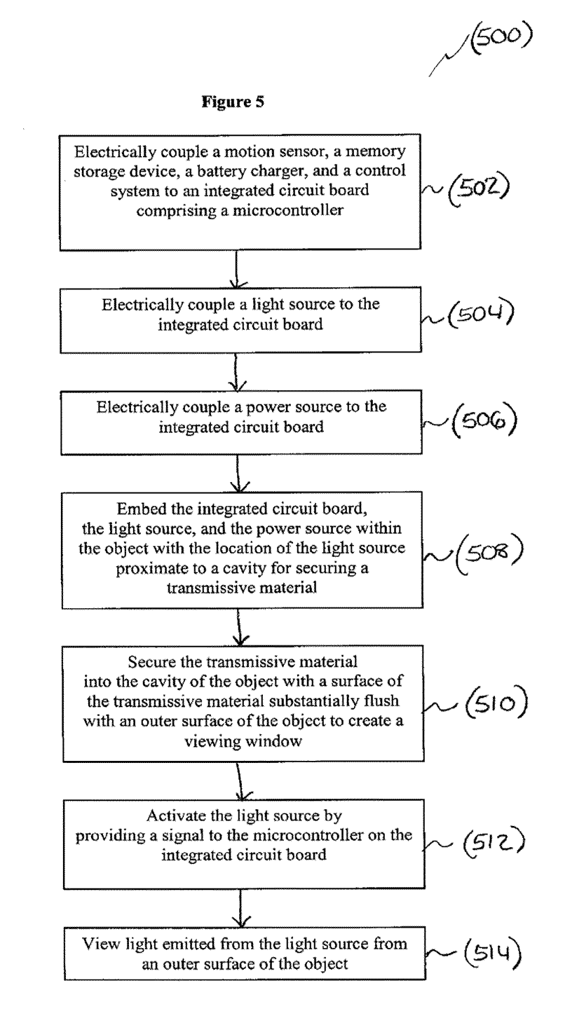

FIG. 5 illustrates an exemplary method of manufacturing a representative embodiment the present invention (500). A method of manufacturing a luminescent display system, such as the luminescent display system 100, according to various aspects of the present invention, may comprise electrically coupling components to an integrated circuit board comprising the microcontroller 302. The components may comprise the motion sensor 312, the memory storage device, and the battery charger 310 (502). The light source 102 and the power source 106 may be electrically coupled to the integrated circuit board (504, 506). The integrated circuit board 104, the light source 102, and the power source 106 may then be embedded within the object 120 such that the light source 102 is configured to be proximate to the cavity to be occupied by the transmissive material 114 (508). The integrated circuit board 104, the light source 102, and the power source 106 may be disposed between any two layers of material during the manufacturing process for creating the object 120, such as between the layers of wood veneer of a skateboard deck or the layers of plastic of a snowboard base. The transmissive material 114 may be secured into the cavity of the object during manufacturing such that a surface of the transmissive material 114 is configured to be substantially flush with an outer surface of the object, creating a viewing window where the light emitted from the light source 102 may be visible from the outer surface of the object (510). The light source 102 may be activated by the microcontroller 302 in response to a signal, such as a change in acceleration of the object as detected by the motion sensor 312 (512). The light emitted from the light source 102 upon activation may be viewed from an outer surface of the object (514).

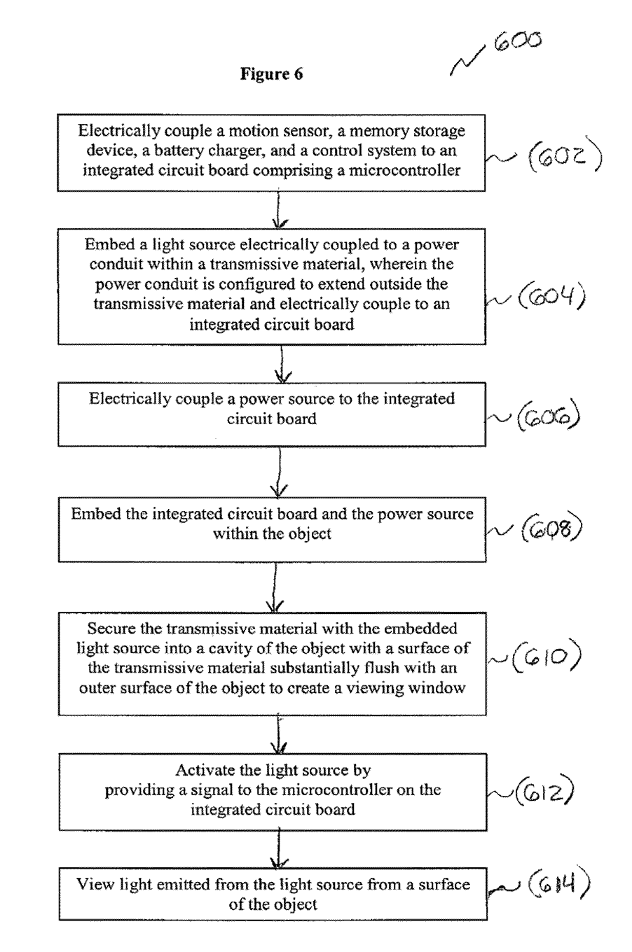

FIG. 6 illustrates another exemplary method of manufacturing a representative embodiment the present invention (600). A method of manufacturing a luminescent display system, such as the luminescent display system 100, according to various aspects of the present invention, may comprise coupling components to an integrated circuit board comprising the microcontroller 302. The components may comprise the motion sensor 312, the memory storage device, and the battery charger 310 (602). The light source 102 may be electrically coupled to a power conduit 112 and embedded within the transmissive material 114 such that the power conduit 112 extends from the embedded light source 102 and outward from the transmissive material 114 for electrically coupling to the integrated circuit board 104 (604). The power source 106 may be electrically coupled to the integrated circuit board (606). The integrated circuit board 104 and the power source 106 may then be embedded within the object (608). The integrated circuit board 104 and the power source 106 may be disposed between any two layers of material during the manufacturing process for creating the object 120, such as between the layers of wood veneer of a skateboard deck or the layers of plastic of a snowboard base. The transmissive material 114 with the embedded light source 102 may be secured into the cavity of the object 120 during manufacturing such that a surface of the transmissive material 114 is configured to be substantially flush with an outer surface of the object, creating a viewing window where the light emitted from the light source 102 may be visible from the outer surface of the object (610). The light source 102 may be activated by the microcontroller 302 in response to a signal, such as a change in acceleration of the object as detected by the motion sensor 312 (612). The light emitted from the light source 102 upon activation may be viewed from an outer surface of the object (614).

In the foregoing description, the invention has been described with reference to specific exemplary embodiments. Various modifications and changes may be made, however, without departing from the scope of the present invention as set forth. The description and figures are to be regarded in an illustrative manner, rather than a restrictive one and all such modifications are intended to be included within the scope of the present invention. Accordingly, the scope of the invention should be determined by the generic embodiments described and their legal equivalents rather than by merely the specific examples described above. For example, the steps recited in any method or process embodiment may be executed in any appropriate order and are not limited to the explicit order presented in the specific examples. Additionally, the components and/or elements recited in any system embodiment may be combined in a variety of permutations to produce substantially the same result as the present invention and are accordingly not limited to the specific configuration recited in the specific examples.

Benefits, other advantages, and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition, system, or apparatus that comprises a list of elements does not include only those elements recited, but may also include other elements not expressly listed or inherent to such process, method, article, composition, system, or apparatus. Other combinations and/or modifications of the above-described structures, arrangements, applications, proportions, elements, materials or components used in the practice of the present invention, in addition to those not specifically recited, may be varied or otherwise particularly adapted to specific environments, manufacturing specifications, design parameters or other operating requirements without departing from the general principles of the same.

The present invention has been described above with reference to an exemplary embodiment. However, changes and modifications may be made to the exemplary embodiment without departing from the scope of the present invention. These and other changes or modifications are intended to be included within the scope of the present invention.

1. A ruggedized luminescent display system for displaying at least one of electronic images and light from an object comprising:
a transmissive material disposed within a cavity of the object, wherein a surface of the transmissive material is configured to be positioned substantially flush with an outer surface of the object;
a light source disposed within the object and configured to emit light through the transmissive material;
an integrated circuit board disposed within the object and electrically coupled to the light source by a first power conduit;
a control system disposed within the object and electrically coupled to the integrated circuit board, wherein the control system comprises a microcontroller configured to control the emission of light from the light source in response to a signal;
a motion sensor disposed within the object and electrically coupled to the integrated circuit board; and
a memory storage device disposed within the object and electrically coupled to the integrated circuit board.

2. The ruggedized luminescent display system according to claim 1, wherein the transmissive material and the light source are at least one of an organic light emitting diode and a quantum dot.

3. The ruggedized luminescent display system according to claim 1, further comprising a power source coupled to the integrated circuit board by a second power conduit and configured to provide power to at least one of the light source, the motion sensor, the memory storage device, and the control system.

4. The ruggedized luminescent display system according to claim 3, wherein the power source comprises at least one of a rechargeable battery, an energy harvesting battery, a thin film battery, a lithium polymer battery, a solar cell, a super capacitor, and an alkaline battery.

5. The ruggedized luminescent display system according to claim 1, wherein the microcontroller is configured to monitor the amount of charge of the power source and the recharging of the power source.

6. The ruggedized luminescent display system according to claim 1, further comprising a switch, wherein the switch is configured provide the signal to the control system when the switch is at least one of activated and deactivated by a user.

7. The ruggedized luminescent display system according to claim 1, wherein the light source is electrically coupled directly onto the integrated circuit board.

8. The ruggedized luminescent display system according to claim 1, wherein the motion sensor, the memory storage device, and the control system are electrically coupled directly onto the integrated circuit board.

9. The ruggedized luminescent display system according to claim 1, wherein the signal comprises at least one of motion, pressure, temperature, and ambient light intensity.

10. The ruggedized display system according to claim 1, wherein the transmissive material comprises at least one of an acrylic material, a composite material, a plastic, a fiber optic sheet, and a luminescent film.

11. The ruggedized luminescent display system according to claim 1, further comprising a reflective film positioned along a surface of the transmissive material facing the cavity of the object, wherein the reflective film is adapted to reflect light emitted from the light source to an opposite side of the transmissive material that is substantially flush with the outer surface of the object.

12. The ruggedized luminescent display system according to claim 1, wherein the transmissive material comprises at least two layers of material and a prismatic film disposed between the at least two of the layers.

13. The ruggedized luminescent display system according to claim 1, wherein the light source comprises at least one of a light emitting diode, an electronic video display, a light emitting electrochemical cell, a thick-film dielectric component, and a micro-display.

14. The ruggedized luminescent display system according to claim 1, wherein the light source is located proximate to the transmissive material.

15. The ruggedized luminescent display system according to claim 1, wherein the light source is embedded within the transmissive material.

16. The ruggedized luminescent display system according to claim 1, wherein the motion sensor comprises at least one of an accelerometer and a piezoelectric transducer.

17. A ruggedized luminescent display system for displaying at least one of an electronic image and light from a boardsport medium comprising:
a transmissive material disposed within a cavity of the boardsport medium, wherein a first surface of the transmissive material is configured to be positioned substantially flush with an outer surface of the object;
a light source configured to emit light through the transmissive material;
an integrated circuit board electrically coupled to the light source by a first power conduit, wherein the integrated circuit board comprises:
a control system electrically coupled onto the integrated circuit board comprising a microcontroller configured to control the emission of light from the light source in response to a signal;
a motion sensor electrically coupled onto the integrated circuit board; and
a memory storage device electrically coupled onto the integrated circuit board; and
a power source coupled to the integrated circuit board by a second power conduit and configured to provide power to at least one of the light source, the motion sensor, the memory storage device, and the control system;
wherein the light source and the integrated circuit board are disposed within the boardsport medium and secured therein such that the light source and the integrated circuit board are protected from the environmental conditions outside of the boardsport medium; and
wherein the light emitted through the transmissive material by the light source is visible from the outside of the boardsport medium.

18. The ruggedized luminescent display system according to claim 17, wherein the boardsport medium is at least one of a conventional skateboard or snowboard, wherein the skateboard and snowboard comprise a plurality of layers of component material.

19. The ruggedized luminescent display system according to claim 18, wherein at least one of the light source, the integrated circuit board, the power source, and the power conduit are embedded between two of the layers of the component material during the manufacturing of the skateboard and snowboard.

20. The ruggedized luminescent display system according to claim 18, wherein the integrated circuit board and the power source are positioned at an end of the skateboard and the light source and the transmissive material are located on the bottom side of the skateboard between the wheels trucks.

21. The ruggedized luminescent display system according to claim 17, wherein the power source comprises at least one of a rechargeable battery, an energy harvesting battery, a thin film battery, a lithium polymer battery, a solar cell, a super capacitor, and an alkaline battery.

22. The ruggedized luminescent display system according to claim 17, wherein the microcontroller is configured to monitor the amount of charge of the power source and the recharging of the power source.

23. The ruggedized luminescent display system according to claim 17, wherein the transmissive material and the light source are at least one of an organic light emitting diode and a quantum dot.

24. The ruggedized luminescent display system according to claim 17, wherein the light source is electrically coupled directly onto the integrated circuit board.

25. The ruggedized luminescent display system according to claim 17, wherein the signal comprises at least one of motion, pressure, temperature, and ambient light intensity.

26. The ruggedized luminescent display system according to claim 17, wherein the transmissive material comprises at least one of an acrylic material, a composite material, a plastic, a fiber optic sheet, and a luminescent film.

27. The ruggedized luminescent display system according to claim 17, further comprising reflective film positioned along a surface of the transmissive material facing the cavity of the object, wherein the reflective film is adapted to reflect light emitted from the light source to an opposite side of the transmissive material that is substantially flush with the outer surface of the object.

28. The ruggedized luminescent display system according to claim 17, wherein the transmissive material comprises at least two layers of material and a prismatic film disposed between at least two of the layers.

29. The ruggedized luminescent display system according to claim 17, wherein the light source comprises at least one of a light emitting diode, a light emitting electrochemical cell, a thick-film dielectric component, and a micro-display.

30. The ruggedized luminescent display system according to claim 17, wherein the light source is located proximate to the transmissive material.

31. The ruggedized luminescent display system according to claim 17, wherein the light source is embedded inside the transmissive material.

32. The ruggedized luminescent display system according to claim 17, further comprising a switch, wherein the switch is configured provide the signal to the control system when the switch is at least one of activated and deactivated by a user.

33. The ruggedized luminescent display system according to claim 17, wherein the motion sensor comprises at least one of an accelerometer and a piezoelectric transducer.

34. A method of displaying at least one of electronic images or light from a surface of a boardsport medium, comprising;
securing a resilient transmissive material into a cavity of the boardsport medium, wherein a surface of the resilient transmissive material is configured to be substantially flush with an outer surface of the boardsport medium;
mounting a light source within the boardsport medium and configuring the light source to emit light through the resilient transmissive material such that the light emitted by the light source is visible from the outer surface of the boardsport medium;
electrically coupling an integrated circuit board to a motion sensor, a memory storage device, and a control system comprising a microcontroller configured to control the emission of light from the light source in response to a signal; and
electrically coupling the light source to the integrated circuit board that is electrically coupled to the motion sensor, the memory storage device, and the control system and securing the integrated circuit board within the boardsport medium.

35. A method of displaying at least one of electronic images or light from a surface of a boardsport medium according to claim 34, wherein the boardsport medium comprises at least one of a skateboard and a snowboard, wherein the skateboard and snowboard comprise a plurality of layers of component material.

36. A method of displaying at least one of electronic images or light from a surface of a boardsport medium according to claim 35, wherein the light source, the integrated circuit board, the motion sensor, the memory storage device, and the control system are embedded between two of the layers of the component material during the manufacturing of the skateboard and snowboard.
